(19) United States
(12) Patent Application Publication
(10) Pub. No.: US 2008/0238495 A1
(43) Pub. Date: Oct. 2, 2008

(54) FREQUENCY SYNTHESIZER AND WIRELESS COMMUNICATION DEVICE UTILIZING THE SAME

(75) Inventors: RYOICHI TACHIBANA, Kawasaki-shi (JP); Shoji Otaka, Yokohama-shi (JP); Osamu Watanabe, Chigasaki-shi (JP); Hiroaki Hoshino, Yokohama-shi (JP)

Correspondence Address: Charles N.J. Ruggiero, Esq.;Ohlandt , Greeley, Ruggiero & Perle, L.L.P., 10th Floor, One Landmark Square, Stamford, CT, 06901-2682, US

(73) Assignee: Kabushiki Kaisha Toshiba

(21) Appl. No.: 12/051,088

(22) Filed: Mar. 19, 2008

(30) Foreign Application Priority Data
Mar. 22, 2007 (JP) 2007-075501

(51) Int. Cl. H03B 21/00

(52) U.S. Cl. 327/105

(57) ABSTRACT

A frequency synthesizer includes a voltage-controlled oscillator to output an oscillation signal of a oscillating frequency in correspondence with a oscillation controlling voltage that is input to the oscillator, a first frequency-divider to subject the oscillation signal to frequency-division and output a first frequency signal, a second frequency-divider to subject the first frequency signal to frequency-division and output a second frequency signal, a controlling voltage generator to generate the oscillation controlling voltage corresponding to a phase difference between a reference clock signal and the second frequency signal, a frequency detector to detect a frequency difference between the second frequency signal and the reference clock signal, and a controller which controls a free-running frequency of the first frequency divider to minimize the frequency difference.

### CROSS-REFERENCE TO RELATED APPLICATIONS

This application is based upon and claims the benefit of priority from prior Japanese Patent Application No. 2007-075501, filed Mar. 22, 2007, the entire contents of which are incorporated herein by reference.

### BACKGROUND OF THE INVENTION

1. Field of the Invention

The present invention relates to a frequency synthesizer with an expanded operation frequency range.

2. Description of the Related Art

The transmitter/receiver of a wireless communication device in general comprises a frequency synthesizer that can synthesize a frequency in a certain range. A frequency here indicates a mean frequency of a communication channel used in a wireless system, for example. The frequency range varies among wireless systems, but is usually around several tens to several hundreds of megahertz.

A frequency synthesizer employs a phase locked loop (PLL) mainly incorporating a voltage-controlled oscillator (VCO), a divider (programmable divider), a phase detector and a loop filter. In general, a programmable divider does not have a wide operation frequency range, which prevents the divider from performing a dividing operation on high frequencies. For this reason, a certain type of divider called a prescaler, which has a fixed dividing ratio, is inserted upstream from the programmable divider so that a signal can be divided to a frequency level on which the programmable divider can operate.

When the frequency is high, a divider adopting an injection lock system is generally utilized as a prescaler in order to reduce power consumption. The injection lock system is a technology with which a signal of a predetermined frequency is injected into an oscillator in a free-running state so that the frequency of the oscillator is locked onto the predetermined frequency of the signal, and such a technology can be applied to a divider. As the injection power increases, the lockable frequency range expands. However, when the frequency of the signal is around tens of gigahertz, the lockable frequency range is no higher than 1 to 2 GHz no matter how much the injection power is raised. This means that a general prescaler may become unable to divide signals in a millimeter-wave band. Thus, if a prescaler is applied to the frequency synthesizer, there is a possibility of being unable to synthesize a desired frequency.

In light of the above, C. Cao, et al. suggest in “A 50-GHz Phase-Locked Loop in 130nCMOS”, IEEE Custom Integrated Circuits Conference, 2006, pp. 21-24 (hereinafter, referred to as the “related art”) that, when a divider of the injection lock system is adopted as a prescaler, a frequency tuning function should be added. In FIG. 2 of the related art, the VCO and the divider that is used as a prescaler have similar circuitry, where the values for inductances L7 and L8 or capacitances C3 and C4 are determined so as to set the resonant frequency of the divider to half the oscillating frequency of the VCO. In such a structure, a frequency tuning signal Vₜᵤₙₑ is applied to the varactors C3 and C4 of the divider as well as to the varactors C1 and C2 of the VCO, allowing the frequencies of the VCO and the divider to be adjusted at the same time. As a result, the prescaler can perform the dividing operation in the same frequency range as the VCO, in effect.

Because the structure of the related art requires the divider to have the same circuitry as the VCO, the divider needs to include an inductor as one of the structural components. The inductor, however, often takes up more space on an integrated circuit than a capacitor and a resistor, and thus increases the entire size of the circuit and also the cost of production. For millimeter-wave-band signals, a transmission line (distributed constant line) may be adopted in place of an inductor as a discrete element, but this increases the size still further than a circuit incorporating an inductor. In addition, if there is too much variation in production, the structure of the related art cannot achieve the synchronized operations of the VCO and the divider as desired, which would reduce yields.

### BRIEF SUMMARY OF THE INVENTION

According to an aspect of the invention, there is provided a frequency synthesizer comprising: a voltage-controlled oscillator to output an oscillation signal of a oscillating frequency in correspondence with a oscillation controlling voltage that is input to the oscillator; a first frequency-divider to subject the oscillation signal to frequency-division and output a first frequency signal; a second frequency-divider to subject the first frequency signal to frequency-division and output a second frequency signal; a controlling voltage generator to generate the oscillation controlling voltage corresponding to a phase difference between a reference clock signal and the second frequency signal; a frequency detector to detect a frequency difference between the second frequency signal and the reference clock signal; and a controller which controls a free-running frequency of the first frequency divider to minimize the frequency difference.

According to another aspect of the invention, there is provided a wireless communication device comprising: a voltage-controlled oscillator to generate a local signal of a oscillating frequency in correspondence with a oscillation controlling voltage that is input to the oscillator; a first frequency-divider to subject the local signal to frequency-division and output a first frequency signal; a second frequency-divider to subject the first frequency signal to frequency-division and output a second frequency signal; a controlling voltage generator to generate the oscillation controlling voltage corresponding to a phase difference between a reference clock signal and the second frequency signal; a frequency detector to detect a frequency difference between the second frequency signal and the reference clock signal; a controller which controls a free-running frequency of the first frequency divider to minimize the frequency difference; and a frequency converter to perform frequency conversion on either a transmission signal or a reception signal by use of the local signal.

The present invention offers a frequency synthesizer which comprises a prescaler with an expanded operation frequency range while preventing the area from increasing due to the incorporation of an inductor or a transmission line and the yield from reducing due to production variations.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

FIG. 1 is a block diagram showing the structure of a frequency synthesizer according to the first embodiment.

FIG. 2 is the plot of the relationship, in the prescaler of FIG. 1 free-running at a frequency fₚᵣₑₛ, between the input power Pᵢₙ and a lockable frequency band f_{bw} of the prescaler.

FIG. 3 is a diagram showing an example of circuitry for the VCO of FIG. 1.

FIG. 4 is a diagram showing an example of circuitry for the prescaler of FIG. 1.

FIG. 5 is a diagram showing an example of circuitry for the first free-running frequency tuning circuit of FIG. 4.

FIG. 6 is a diagram showing another example of circuitry for the first free-running frequency tuning circuit of FIG. 4.

FIG. 7 is a diagram showing an example of circuitry for the second free-running frequency tuning circuit of FIG. 4.

FIG. 8 is a flowchart showing the process procedure of tuning the free-running frequency of the prescaler of FIG. 1.

FIG. 9 is a block diagram showing a frequency synthesizer according to the second embodiment.

FIG. 10 is a block diagram showing a wireless communication device according to the third embodiment.

FIG. 11 is a diagram showing an example of the prescaler of FIG. 1 or 9 composed of a ¼ frequency dividing circuit.

### DETAILED DESCRIPTION OF THE INVENTION

The embodiments of the present invention will be explained with reference to the drawings.

### Embodiment 1

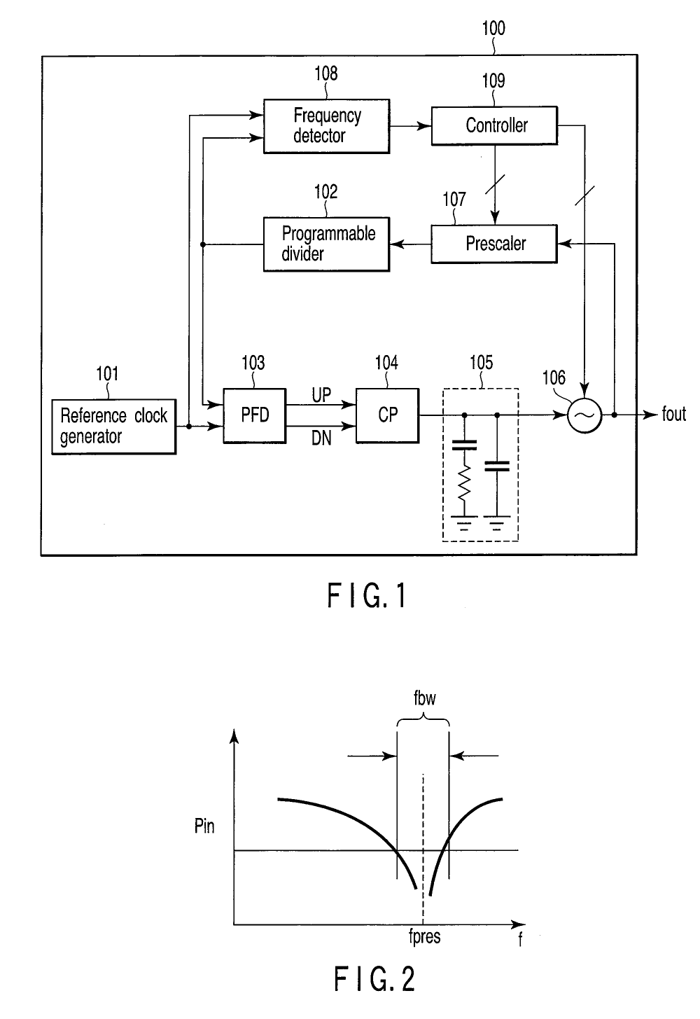

As illustrated in FIG. 1, a frequency synthesizer 100 according to the first embodiment of the present invention comprises a reference clock generator 101, a programmable divider 102, a phase frequency detector (PFD) 103, a charge pump (CP) 104, a loop filter 105, a voltage-controlled oscillator (VCO) 106, a prescaler 107, a frequency detector 108 and a controller 109. The reference clock generator 101, the programmable divider 102, the PFD 103, the CP 104, the loop filter 105, the VCO 106 and the prescaler 107 form a so-called PLL.

The PLL of the frequency synthesizer 100 will be first described.

The reference clock generator 101 generates a reference clock signal of a reference frequency f_{ref}. The reference clock signal is input to a reference phase input terminal of the PFD 103. The reference clock generator 101 may be externally arranged.

The programmable divider 102 is designed in a manner that the dividing ratio is programmable. The programmable divider 102 further divides a first division signal of a frequency fₒᵤₜ/Nₚᵣₑₛ obtained by the prescaler 107, by a variable dividing ratio N_{prog} so as to output a second division signal of a frequency fₒᵤₜ/(Nₚᵣₑₛ*N_{prog}). The second division signal is input to the oscillation phase input terminal of the PFD 103.

The PFD 103 detects a phase difference between the reference phase and the oscillation phase. In other words, the PFD 103 outputs a phase difference signal determined in accordance with the phase difference between the reference clock signal input into the reference phase input terminal and the second division signal input into the oscillation phase input terminal. The phase difference signal is input to the CP 104. The PFD 103 may simply be a phase detector.

The CP 104 may be a booster circuit constituted by a capacitor and a switch, and the CP 104 is designed to amplify the phase difference signal received from the PFD 103. The amplified phase difference signal is input to the loop filter 105. The loop filter 105 may be a low-pass filter (LPF) constituted by a resistor and a capacitor (RC), and the loop filter 105 is designed to remove high-frequency components from the signal amplified by the CP 104. The signal filtered in this manner is input to the VCO 106 as a frequency tuning signal Vₜᵤₙₑ.

The VCO 106 is an oscillator that oscillates at a frequency in correspondence with the frequency tuning signal Vₜᵤₙₑ that is received. The VCO 106 that has received the frequency tuning signal Vₜᵤₙₑ adopts a sinusoidal signal of a frequency fₒᵤₜ as an oscillation output. The oscillation output of the frequency fₒᵤₜ is input into the prescaler 107.

The prescaler 107 is, so to speak, a pre-divider, dividing the oscillation output from the VCO 106 prior to the division carried out by the programmable divider 102. When the oscillation output of the frequency fₒᵤₜ is received from the VCO 106, the prescaler 101 divides the output by a fixed or variable dividing ratio Nₚᵣₑₛ. The first division signal of the frequency fₒᵤₜ/Nₚᵣₑₛ thereby obtained is input to the aforementioned programmable divider 102.

By repeating this loop, the frequency fₒᵤₜ of the oscillation output from the VCO 106 converges to (locks onto) the product of the reference clock f_{ref}, the dividing ratio Nₚᵣₑₛ of the prescaler 107 and the dividing ratio N_{prog} of the programmable divider 102, f_{ref}*Nₚᵣₑₛ*N_{prog}.

There is a limit, however, to the frequency control by the VCO 106 by use of the frequency tuning signal Vₜᵤₙₑ only.

According to the present embodiment, the frequency synthesizer 100 roughly tunes the free-running frequency prior to fine-tuning the oscillating frequency of the VCO 106 by use of the frequency tuning signal Vₜᵤₙₑ so that the VCO 106 can be smoothly locked onto a desired frequency.

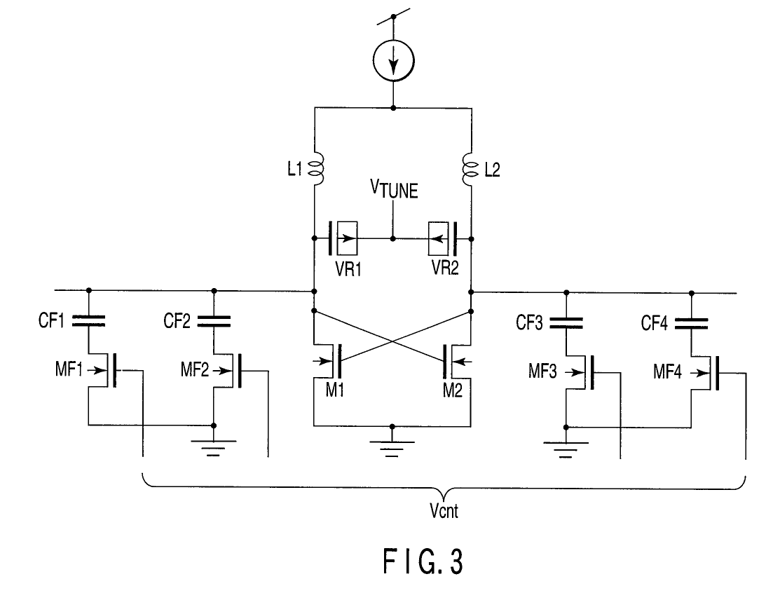

The VCO 106 may be a parallel resonator as illustrated in FIG. 3, which is constituted by inductors L1 and L2, and varactors VR1 and VR2 whose capacitances are determined by the frequency tuning signal Vₜᵤₙₑ. Furthermore, the resonator includes negative resistors that are formed by metal-oxide semiconductor field-effect transistors (MOSFETs) M1 and M2 and connected to each other in parallel in order to cancel a resistance component, which is a loss for the resonator. In addition, capacitors CF1, CF2, CF3 and CF4 are also arranged in the resonator so as to realize the aforementioned rough tuning of the free-running frequency, and these capacitors are configured in such a manner that their connection to the ground is controlled by switches MF1, MF2, MF3 and MF4 that are turned on/off by a control signal V_{cnt} provided from the controller 109, which will be discussed later. The oscillating frequency of the VCO 106 changes in accordance with the fixed inductance determined by the inductors L1 and L2 and the variable capacitance determined by the varactors VR1 and VR2 and the capacitor CF1-CF4.

Next, the rough tuning of the free-running frequency of the VCO 106 will be described.

The frequency detector 108 includes two input terminals. The first input terminal of the frequency detector 108 receives the second division signal of the frequency fₒᵤₜ/(N_{prog}*Nₚᵣₑₛ) from the programmable divider 102, while the second input terminal receives the reference clock signal of the frequency f_{ref} from the reference clock generator 101. The frequency detector 108 compares the frequencies fₒᵤₜ/(N_{prog}*Nₚᵣₑₛ) and f_{ref} of the two input signals, and sends a comparison result signal to the controller 109.

In response to the comparison result signal from the frequency detector 108, the controller 109 determines the control signal V_{cnt}. The control signal V_{cnt} is applied to the gates of the switches MF1-MF4, and the capacitors CF1-CF4 are connected or disconnected in accordance with the ON/OFF states of the switches MF1-MF4, respectively. The controller 109 determines the control signal V_{cnt} in a trial-and-error manner so that a difference between the frequency fₒᵤₜ/(N_{prog}*Nₚᵣₑₛ) and the frequency f_{ref} of the reference clock, fₒᵤₜ/(N_{prog}*Nₚᵣₑₛ)−f_{ref}, is lessened. In other words, the control signal V_{cnt} is determined so as to minimize the frequency difference fₒᵤₜ/(N_{prog}*Nₚᵣₑₛ)−f_{ref}.

As discussed above, the controller 109 changes the free-running frequency so that the VCO 106 is locked onto a desired frequency. When the above rough-tuning process is completed, the VCO 106 is ready to find the frequency tuning signal Vₜᵤₙₑ through the aforementioned PLL so as to be locked accurately onto a desired frequency (fine tuning).

In the above-mentioned rough tuning of the free-running frequency of the VCO 106, however, the prescaler 107 cannot conduct a normal operation on a high frequency such as in a band of several tens of gigahertz. For this reason, the frequency synthesizer 100 actually performs tuning on the free-running frequency fₚᵣₑₛ of the prescaler 107 under the same concept as the aforementioned rough tuning of the free-running frequency of the VCO 106, prior to the rough tuning of the free-running frequency of the VCO 106.

The tuning operation of the free-running frequency fₚᵣₑₛ of the prescaler 107 will be discussed below. As indicated in FIG. 2, the prescaler 107 needs more input power as the frequency that is to be locked on is farther away from the free-running frequency. In the graph of FIG. 2, the vertical axis indicates the input power Pᵢₙ, the horizontal axis indicates the frequency f, f_{bw} denotes a lockable frequency band of the prescaler 107 with respect to the input power Pᵢₙ, and fₚᵣₑₛ denotes the free-running frequency of the prescaler 107.

The free-running frequency fₚᵣₑₛ of the prescaler 107 is tuned by a loop formed by the reference clock generator 101, the programmable divider 102, the frequency detector 108, the controller 109 and the prescaler 107.

The target frequency f_{ref}*N_{prog}*Nₚᵣₑₛ is already known, and the programmable divider 102 is provided with the dividing ratio N_{prog}. At this moment, the prescaler 107 is free-running at the free-running frequency fₚᵣₑₛ. The tuning is conducted in such a manner as to bring the free-running frequency of the prescaler 107 closer to the target frequency f_{ref}*N_{prog}.

In particular, the first division signal is divided by the programmable divider 102 and input as the second division signal of the frequency fₚᵣₑₛ/N_{prog} to the first input terminal of the frequency detector 108.

On the other hand, the reference clock signal of the frequency f_{ref} generated by the reference clock generator 101 is input to the second input terminal of the frequency detector 108. The frequency detector 108 compares the frequencies fₚᵣₑₛ/N_{prog} and f_{ref} of the two input signals, and sends a comparison result signal to the controller 109.

In response to the comparison result signal from the frequency detector 108, the controller 109 generates at least one of control signals F_{cnt1} and F_{cnt2} to tune the free-running frequency fₚᵣₑₛ of the prescaler 107. That is, the controller 109 determines at least one of the control signals F_{cnt1} and F_{cnt2} in a trial-and-error manner so as to minimize the difference between the frequency fₚᵣₑₛ/N_{prog} and the reference clock f_{ref}.

Next, the operation of tuning the free-running frequency fₚᵣₑₛ of the prescaler 107 will be explained in detail.

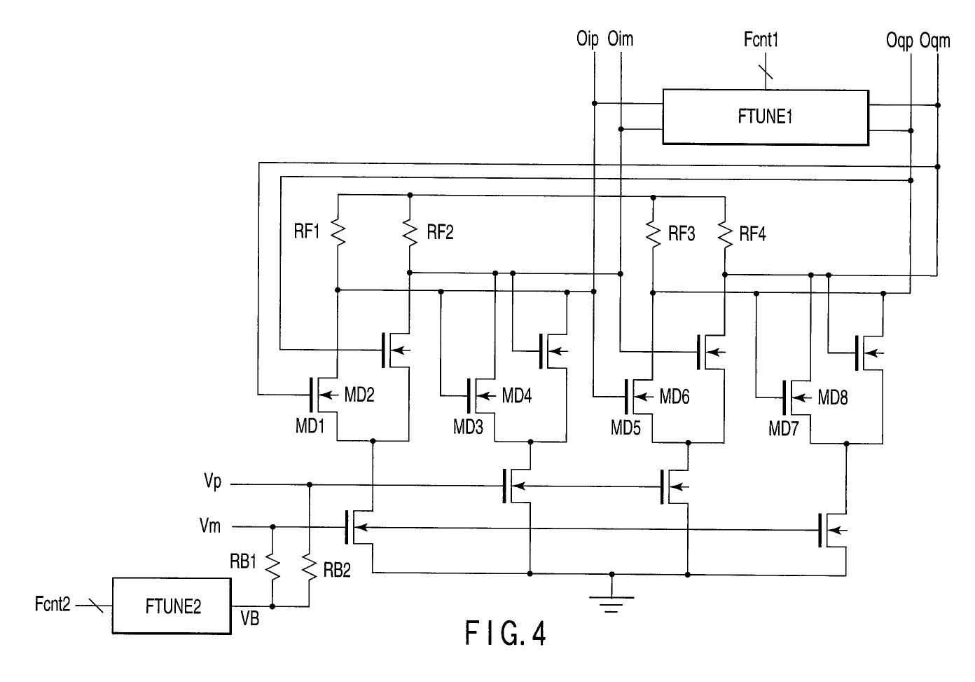

The prescaler 107 incorporates a flip-flop circuit as shown in FIG. 4. The free-running frequency tuning circuits FTUNE1 and FTUNE2 are designed to tune the free-running frequency fₚᵣₑₛ, and either one of the circuits may be selectively used, or both may be used in combination. In the circuit of FIG. 4, division output signals Oip, Oim, Oqp and Oqm are obtained from an input signal Vₚ and Vₘ. The bias current is determined by the values of the resistors RB1 and RB2 and a bias voltage VB in the circuit of FIG. 4. The free-running frequency fₚᵣₑₛ of the prescaler 107 is determined by the oscillating frequency of the paths of MOSFETs MD1-MD8, even before applying signals to the input voltages Vₚ and Vₘ. The MOSFETs MD1 and MD2 detect a difference signal between the output signals Oqp and Oqm, which is given positive feedback and amplified by the MOSFETs MD3 and MD4 so as to obtain output signals Oip and Oim. At the same time, the MOSFETs MD5 and MD6 detect a difference signal between the output signals Oip and Oim, which is given positive feedback and amplified by the MOSFETs MD7 and MD8 so as to obtain output signals Oqp and Oqm. By repeating this operation, the prescaler 107 oscillates at a free-running frequency fₚᵣₑₛ.

In the circuit, it is assumed that the load resistors RF1-RF4 have the same resistance RF, and the MOSFETs MD1-MD8 are of the same size. The free-running frequency fₚᵣₑₛ of the prescaler 107 is proportionate to the inverse of the time constant of the output terminal, or in other words to the inverse of RF*(2C_{gs}+2C_{db}) where C_{gs} and C_{db} denote the gate-source capacitance and drain-body capacitance of the MOSFETs MD1-MD8, respectively. The free-running frequency tuning circuits FTUNE1 and FTUNE2 illustrated in FIG. 4 tune the free-running frequency fₚᵣₑₛ of the prescaler 107 by varying this time constant. The free-running frequency tuning circuit FTUNE1 tunes the free-running frequency fₚᵣₑₛ of the prescaler 107 by controlling the capacitance or resistance that is to be applied to the output terminal. The free-running frequency tuning circuit FTUNE2 changes the drain-body voltage Vdb of the MD1-MD8 by controlling the bias voltage VB. Because of the drain-body capacitance C_{db} which depends on the drain-body voltage Vdb, the aforementioned time constant RF*(2C_{gs}+2C_{db}) can be varied, thereby allowing the free-running frequency circuit FTUNE2 to tune the free-running frequency fₚᵣₑₛ of the prescaler 107.

Next, an example of the circuitry of the first free-running frequency tuning circuit FTUNE1 illustrated in FIG. 4 will be discussed with reference to FIG. 5.

FIG. 5 shows a partial circuit that is connected to the output terminal Oqp only, but similar partial circuits are connected also to the other three output terminals Oip, Oim and Oqm. More specifically, each of the output terminals is connected to two load capacitors CF10 and CF11, which are connected to and disconnected from a ground by way of the switches MF10 and MF11 that are turned on/off by the control signal F_{cnt1}. In this example, two load capacitors are arranged in parallel, but any number of load capacitors may be incorporated in parallel. The circuit FTUNE1 can apply to the output terminals different levels of load capacitance that correspond to 2 raised to the power of the number of load capacitors connected in parallel (when all the load capacitors have different capacitances). Thus, tuning can be made more finely as the number of load capacitances increases. The example includes two load capacitors in parallel, which means the load capacitance applied to the output terminals is one of four levels, 0, CF10, CF11, and CF10+CF11. Because the free-running frequency fₚᵣₑₛ of the prescaler 107 is proportionate to the inverse of the time constant of the output terminals, the controller 109 determines the control signal F_{cnt1} in such a manner that a smaller load capacitance is chosen when the free-running frequency fₚᵣₑₛ of the prescaler 107 is low, while a larger load capacitance is chosen when the frequency is high.

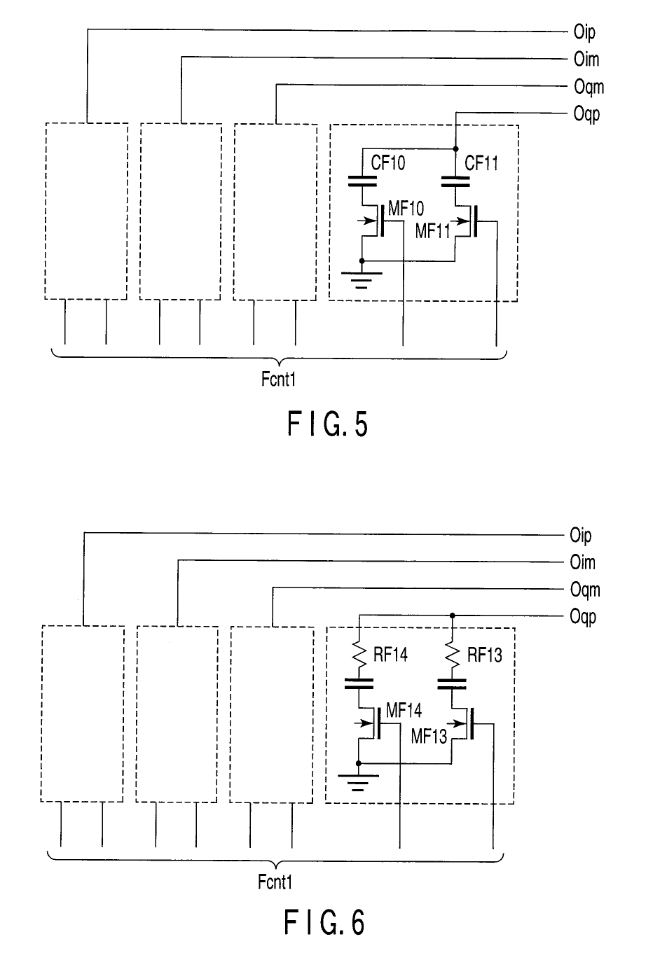

Another example of the circuitry of the first free-running frequency tuning circuit FTUNE1 shown in FIG. 4 will be discussed with reference to FIG. 6.

FIG. 6 shows a partial circuit that is connected to the output terminal Oqp only, but similar partial circuits are connected also to the other three output terminals Oip, Oim and Oqm. In other words, each of the output terminals is connected to two load resistors RF13 and RF14, which are connected to and disconnected from the ground by the switches MF13 and MF14 that are turned on/off by the control signal F_{cnt1}. The capacitors between the switches and the load resistors are meant for direct-current blocking, and therefore do not have anything to do with adjustment of the time constant. The example shows two load resistors in parallel, but any number of load resistors may be arranged in parallel. The free-running frequency tuning circuit FTUNE1 can apply to the output terminals different levels of load resistor that correspond to 2 raised to the power of the number of load resistors that are connected in parallel (when all the load resistors have different resistance values). Thus, an arrangement with more load resistors in parallel can realize finer tuning. Because the example incorporates two load resistors in parallel, the load resistor that can be applied to the output terminals is one of four levels, 0, RF13, RF14, and (RF13*RF14)/(RF13+RF14). The free-running frequency fₚᵣₑₛ of the prescaler 107 is proportionate to the inverse of the time constant of the output terminals, and therefore the controller 109 determines the control signal F_{cnt1} in such a manner that a smaller load resistance is chosen when the free-running frequency fₚᵣₑₛ of the prescaler 107 is low, while a larger load resistance is chosen when the frequency is high.

FIGS. 5 and 6 are presented as examples of the first free-running frequency tuning circuit FTUNE1 shown in FIG. 4, but these examples may be combined to constitute another free-running frequency tuning circuit FTUNE1. That is, any desired number of load resistors and capacitors may be connected in parallel and switched around so that both the capacitance and load resistance that are applied to the output terminals can be varied. The capacitors and load resistors may include some that have the same level or they all may have different values.

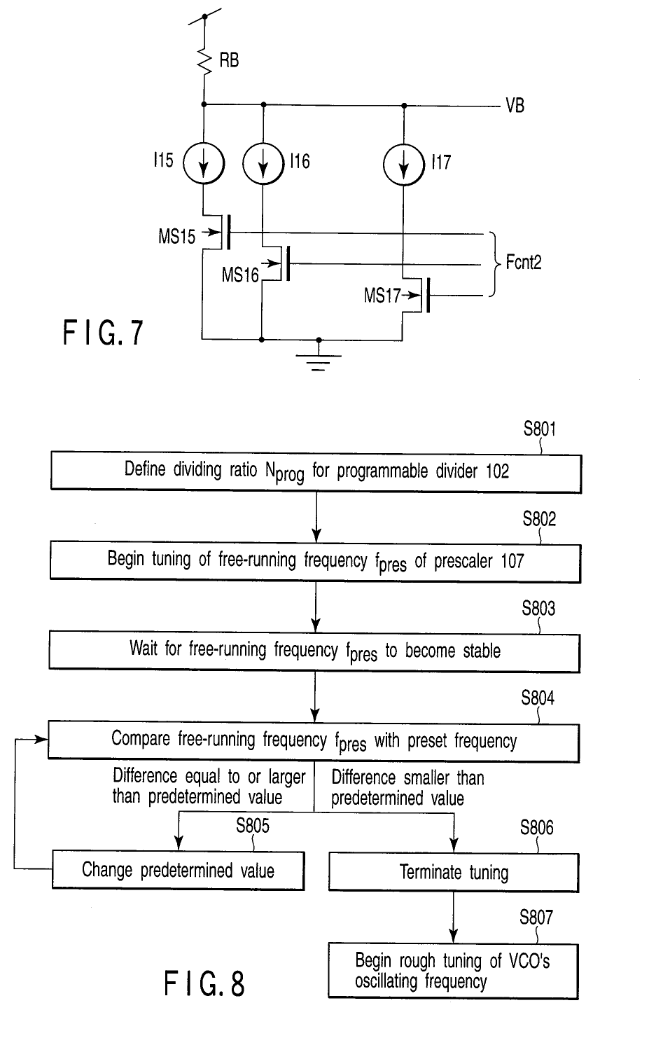

Next, the structure of the second free-running frequency tuning circuit FTUNE2 illustrated in FIG. 4 will be discussed with reference to FIG. 7.

As shown in FIG. 7, the bias terminal VB is connected to three current sources I15-I17, which are connected to and disconnected from the ground by switches MS15-MS17 turned on/off by the control signal F_{cnt2}. A load resistor RB is arranged between the bias terminal VB and the power VDD. In this example, three current sources are arranged in parallel, but any number of current sources may be incorporated. The circuit FTUNE2 can adjust the bias voltage VB into different levels that correspond to the 2 raised to the power of the number of current sources that are connected in parallel (when all the current sources output different currents). Thus, more current sources in parallel can realize finer adjustment. Because the example includes three current sources in parallel, the bias voltage can be one of eight levels, 0, VDD−I15*RB, VDD−I16*RB, VDD−I17*RB, VDD−(I15+I16)*RB, VDD−(I16+I17)*RB, VDD−(I15+I17)*RB, and VDD−(I15+I16+I17)*RB. By changing the voltage of the bias terminal VB, the current that flows into the MOSFET MD1-MD8 of FIG. 4 changes, as a result of which the drain-body voltage Vdb of the MD1-MD8 changes. Since the drain-body capacitance C_{db} has a characteristic of monotonously decreasing with respect to the drain-body voltage Vdb, the controller 109 determines the control signal F_{cnt2} in such a manner as to increase the drain-body voltage Vdb when the free-running frequency fₚᵣₑₛ of the prescaler 107 is low, and to lower the drain-body voltage Vdb when the frequency is high.

As discussed above, the frequency synthesizer 100 tunes the free-running frequency fₚᵣₑₛ of the prescaler 107 by use of the free-running frequency tuning circuits FTUNE1 and FTUNE2 that are controlled by the control signals F_{cnt1} and F_{cnt2}. During the tuning of the free-running frequency fₚᵣₑₛ of the prescaler 107, the PFD 103 and CP 104 are not required in principle, and thus may be put into an operational or non-operational state. From the aspect of power saving, however, it is preferable that the PFD 103 and CP 104 be kept in a non-operational state.

The process of tuning the free-running frequency fₚᵣₑₛ of the prescaler 107 will now be explained with reference to the flowchart of FIG. 8.

First, when a target frequency f_{ref}*Nₚᵣₑₛ*N_{prog} is provided, the dividing ratio N_{prog} is defined for the programmable divider 102 (STEP S801). Next, the controller 109 begins the tuning of the free-running frequency fₚᵣₑₛ of the prescaler 107 (STEP S802). More specifically, the controller 109 generates at least one of control signals F_{cnt1} and F_{cnt2} in response to the comparison result signal received from the frequency detector 108. Because the free-running frequency fₚᵣₑₛ that is just tuned is unstable, the system waits for the frequency to become stable (STEP S803). After the free-running frequency fₚᵣₑₛ becomes stable, the frequency detector 108 compares the frequency fₚᵣₑₛ/N_{prog} of the second division signal from the programmable divider 102 with the reference frequency f_{ref} (STEP S804). As a result of comparison, if the difference between the two frequencies fₚᵣₑₛ/N_{prog}−f_{ref} is found to be below a predetermined value, the tuning is terminated (STEP S806), and the rough tuning of the VCO 106 is initiated (STEP S807). On the other hand, as a result of comparison at STEP S804, if the difference between the two frequencies fₚᵣₑₛ/N_{prog}−f_{ref} is found to be equal to or exceed the predetermined value, the controller 109 changes the preset value of the control signal, and the process returns to STEP S803 (STEP S805).

As explained above, the frequency synthesizer 100 according to the present embodiment performs the tuning of the free-running frequency fₚᵣₑₛ of the prescaler 107 (first phase), thereafter performs the rough tuning of the free-running frequency of the VCO 106 (second phase), and then carries out the fine tuning of the oscillating frequency of the VCO 106 by use of a PLL (third phase). By incorporating this three-phase frequency tuning, the output frequency fₒᵤₜ of the VCO 106 is locked onto a desired frequency f_{ref}*Nₚᵣₑₛ*N_{prog}. Hence, a frequency synthesizer with a prescaler having an expanded operation frequency range can be provided, while preventing the area from increasing due to the use of an inductor or a transmission line and also preventing the production yield from decreasing due to production variations. This keeps the production cost from increasing.

### Embodiment 2

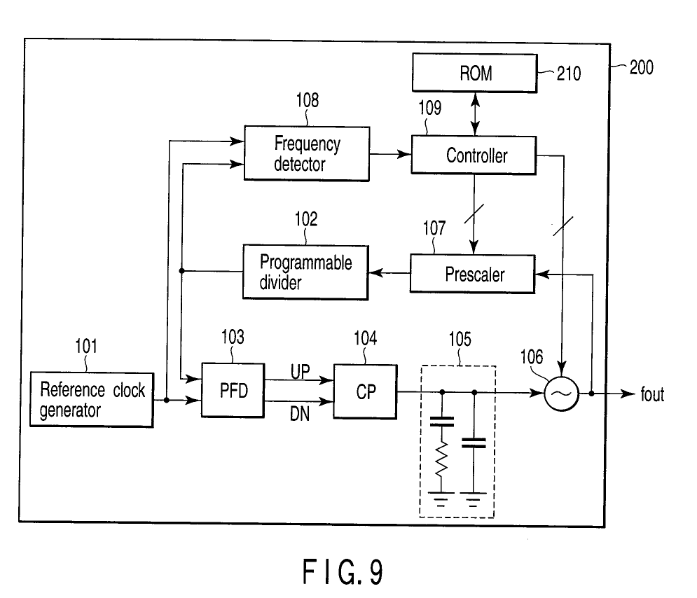

FIG. 9 illustrates a frequency synthesizer 200 according to the second embodiment of the present invention. In the structure of FIG. 9, a ROM 210 is connected to the controller 109 of the frequency synthesizer 100 of FIG. 1. In FIG. 9, components that are the same as those of FIG. 1 are provided with the same reference numerals, and the explanation thereof is omitted. The explanation will focus on where the structure differs from FIG. 1.

According to the first embodiment, the three-phase frequency tuning, which includes the tuning of the free-running frequency fₚᵣₑₛ of the prescaler 107 (first phase), the rough tuning of the oscillating frequency fₒᵤₜ of the VCO (second phase) and the fine tuning of the oscillating frequency fₒᵤₜ (third phase), is conducted in order to lock the output frequency fₒᵤₜ of the VCO 106 to the target frequency f_{ref}*Nₚᵣₑₛ*N_{prog}. In contrast, in the frequency synthesizer 200 according to the present embodiment, several values for the control signals F_{cnt1} and F_{cnt2} and the corresponding values for the free-running frequency fₚᵣₑₛ of the prescaler 107 are stored in the ROM 210 in advance. When the target frequency f_{ref}*Nₚᵣₑₛ*N_{prog} is given, the controller 109 reads from the ROM 210 the F_{cnt1} and F_{cnt2} that correspond to the free-running frequency fₚᵣₑₛ that is the closest to the target frequency. Thus, the aforementioned first-phase tuning can be carried out at high speed. For the free-running frequency fₚᵣₑₛ, all possible values may be stored in the ROM 210, or some of the values may be selected to be stored as typical values.

What is stored in the ROM 210 is not limited to the above, and several values for the control voltage V_{cnt} and the corresponding values for the oscillating frequency fₒᵤₜ of the VCO 106 may be stored, for example. In this manner, the aforementioned second-phase frequency tuning can also be carried out at high speed.

As described above, the free-running frequency of the prescaler according to the present embodiment can be tuned at a higher speed than the first embodiment, by incorporating the ROM that stores in advance several different free-running frequencies that can be dealt with by the controller.

### Embodiment 3

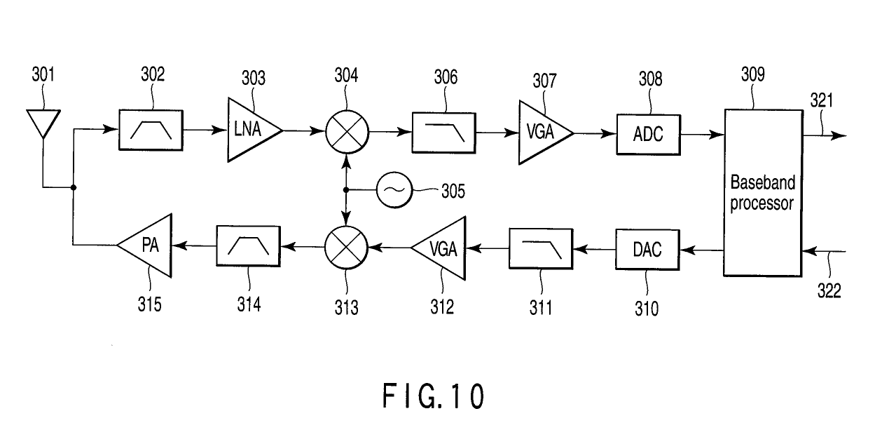

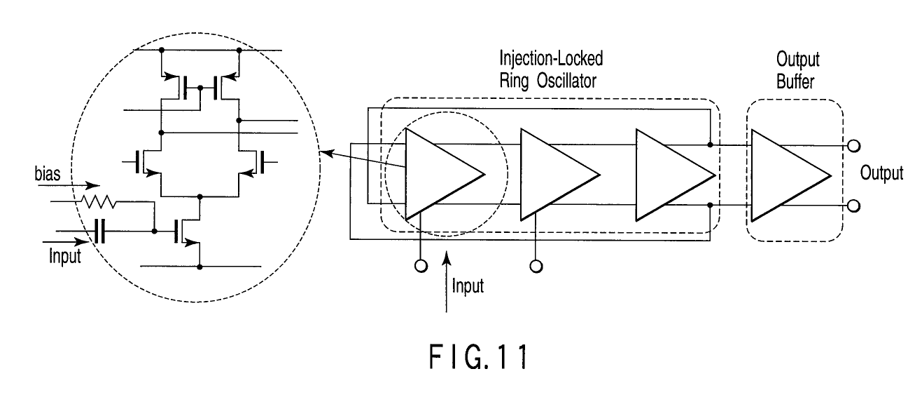

FIG. 10 is a block diagram showing a wireless communication device (wireless transmitter/receiver) according to the third embodiment of the present invention. The aforementioned frequency synthesizer 100 or 200 according to the first or second embodiment is employed as a frequency synthesizer 305. The wireless communication device according to the present embodiment comprises a demodulator and a modulator, each of which includes a mixer.

On the reception side, a high-frequency filter 302 (for example, a band-pass filter) roughly selects a channel for a reception signal, which is an RF signal received by an antenna 301, and then the reception signal is input to a low noise amplifier 303.

The output signal from the low noise amplifier 303 is input to a mixer 304. A local signal is supplied from a frequency synthesizer 305 into the mixer 304. The mixer 304 and the frequency synthesizer 305 form a demodulator, and a baseband signal appears in the vicinity of a direct current as an output of the mixer 304.

In a similar manner to a regular direct-conversion receiver, a base band filter 306 (for instance, a low-pass filter) selectively extracts necessary frequency components from the output signal of the mixer 304. The output signal of the base band filter 306 is amplified by a variable gain amplifier 307 into a signal of amplitude that is suitable for analog-digital conversion, and is then input into an analog-digital converter 308. A digital baseband signal is output from the analog-digital converter 308.

The digital baseband signal is sent to a baseband processor 309. The baseband processor 309 demodulates the digital baseband signal to obtain reception data 321.

On the transmission side, the baseband processor 309 outputs digital baseband signals generated in accordance with transmission data 322. Each of the digital baseband signals is converted to an analog signal (analog modulation signal) by a digital-analog converter 310.

The analog modulation signal that is output from the digital-analog converter 310 is subjected to filtering by a base band filter 311 (for instance, a low-pass filter) to remove unwanted components on the high-frequency side. Furthermore, the filtered signal is amplified by a variable gain amplifier 312 to suitable amplitude, and then input to a mixer 313. A local signal is supplied from the frequency synthesizer 305 to the mixer 313. The mixer 313 and a frequency synthesizer 305 form a modulator, and the mixer 313 outputs a modulated signal of a high frequency.

The modulated signal output from the mixer 313 is subjected to filtering by a high frequency filter (for instance, a band-pass filter) 314 to extract high-frequency components. The output signal of the high-frequency filter 314 is amplified by a power amplifier 315 to a required level of power and supplied to the antenna 301. An RF signal is thereby transmitted from the antenna 301.

As can be seen from the above, the present embodiment realizes a wireless communication device that can deal with a high frequency by use of the frequency synthesizer according to the first or second embodiment.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

In the above embodiments, a flip-flop ½ divider as illustrated in FIG. 4 is employed for the prescaler 107. The use of a differential injection locking ¼ frequency divider comprising a three-stage ring oscillator and an output buffer as shown in FIG. 11 can also produce the same effect.

In addition to the above, the present invention can be equally embodied with various modifications, without departing from the scope of the invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A frequency synthesizer comprising:
a voltage-controlled oscillator to output an oscillation signal of a oscillating frequency in correspondence with a oscillation controlling voltage that is input to the oscillator;
a first frequency-divider to subject the oscillation signal to frequency-division and output a first frequency signal;
a second frequency-divider to subject the first frequency signal to frequency-division and output a second frequency signal;
a controlling voltage generator to generate the oscillation controlling voltage corresponding to a phase difference between a reference clock signal and the second frequency signal;
a frequency detector to detect a frequency difference between the second frequency signal and the reference clock signal; and
a controller which controls a free-running frequency of the first frequency divider to minimize the frequency difference.

2. The frequency synthesizer according to claim 1, wherein a free-running frequency of the voltage-controlled oscillator is controllable by rough tuning, and the controller is configured to perform the rough tuning in accordance with the frequency difference.

3. The frequency synthesizer according to claim 2, wherein the controller performs the rough tuning after controlling the free-running frequency of the first frequency divider.

4. The frequency synthesizer according to claim 1, wherein the first frequency divider includes a tuning unit configured to adjust a time constant by use of the control signal.

5. The frequency synthesizer according to claim 4, wherein the tuning unit is configured to adjust a bias voltage of the first divider by use of the control signal.

6. The frequency synthesizer according to claim 4, wherein the tuning unit is configured to adjust a load resistance of the first frequency divider by use of the control signal.

7. The frequency synthesizer according to claim 1, wherein the tuning unit is configured to adjust a load capacitance of the first frequency divider by use of the control signal.

8. The frequency synthesizer according to claim 1, further comprising:
a storing unit configured to store levels of the control signal and corresponding free-running frequencies of the first frequency divider in correspondence with one another,
wherein the controller reads from the storing unit a value of the control signal that corresponds to a value of the free-running frequency closest to a desired frequency of the oscillation signal, and supplies the value of the control signal to the first frequency divider.

9. The frequency synthesizer according to claim 1 wherein the first frequency divider is a differential injection locking frequency divider.

10. A wireless communication device comprising:
a voltage-controlled oscillator to generate a local signal of a oscillating frequency in correspondence with a oscillation controlling voltage that is input to the oscillator;
a first frequency-divider to subject the local signal to frequency-division and output a first frequency signal;
a second frequency-divider to subject the first frequency signal to frequency-division and output a second frequency signal;
a controlling voltage generator to generate the oscillation controlling voltage corresponding to a phase difference between a reference clock signal and the second frequency signal;
a frequency detector to detect a frequency difference between the second frequency signal and the reference clock signal;
a controller which controls a free-running frequency of the first frequency divider to minimize the frequency difference; and
a frequency converter to perform frequency conversion on either a transmission signal or a reception signal by use of the local signal.

11. The device according to claim 10, wherein a free-running frequency of the voltage-controlled oscillator is controllable by rough tuning, and the controller is configured to perform the rough tuning in accordance with the frequency difference.

12. The device according to claim 11 wherein the controller performs the rough tuning after controlling the free-running frequency of the first frequency divider.

13. The device according to claim 10, wherein the first frequency divider includes a tuning unit configured to adjust a time constant by use of the control signal.

14. The device according to claim 13, wherein the tuning unit is configured to adjust a bias voltage of the first divider by use of the control signal.

15. The device according to claim 13, wherein the tuning unit is configured to adjust a load resistance of the first frequency divider by use of the control signal.

16. The device according to claim 10, wherein the tuning unit is configured to adjust a load capacitance of the first frequency divider by use of the control signal.

17. The device according to claim 10, further comprising:
a storing unit configured to store levels of the control signal and corresponding free-running frequencies of the first frequency divider in correspondence with one another,
wherein the controller reads from the storing unit a value of the control signal that corresponds to a value of the free-running frequency closest to a desired frequency of the local signal, and supplies the value of the control signal to the first frequency divider.

18. The device according to claim 10 wherein the first frequency divider is a differential injection locking frequency divider.
